(19) United States
(12) Patent Application Publication
(10) Pub. No.: US 2025/0011914 A1
(43) Pub. Date: Jan. 9, 2025

(54) COSMETIC FINISH FOR ALUMINUM ALLOYS

(71) Applicant: Apple Inc., Cupertino, CA (US)

(72) Inventors: Zechariah D. Feinberg, Austin, TX (US); Wai Man Raymund Kwok, Hong Kong (HK); Lee E. Hooton, Massapequa, NY (US); James A. Curran, Sunnyvale, CA (US); Elizabeth Nicometo, Cupertino, CA (US); Brian S. Tryon, Redwood City, CA (US); Isabel Yang, San Jose, CA (US); Shinjita Acharya, Sunnyvale, CA (US)

(21) Appl. No.: 18/418,210

(22) Filed: Jan. 19, 2024

Related U.S. Application Data
(60) Provisional application No. 63/512,242, filed on Jul. 6, 2023.

(51) Int. Cl. C23C 14/02; C23C 14/06; C23C 18/16; C23C 18/32; C23C 18/48; C23C 28/00; C25D 3/38; C25D 5/44; C25D 11/04

(52) U.S. Cl. CPC C23C 14/025; C23C 14/0641; C23C 18/1637; C23C 18/1651; C23C 18/1653; C23C 18/32; C23C 18/48; C23C 28/321; C23C 28/345; C25D 5/44; C25D 11/04; C25D 11/16

(57) ABSTRACT

Non-cosmetic quality aluminum substrates are given a cosmetic finish by applying a PVD coating to the substrate. An enclosure for an electronic device can include an aluminum substrate including a 6000 series aluminum or 7000 series aluminum, a PVD coating disposed on the substrate, and a protective underlayer disposed between the aluminum substrate and the PVD coating.

### CROSS-REFERENCE TO RELATED APPLICATION(S)

This claims priority to U.S. Provisional Patent Application No. 63/512,242, filed 6 Jul. 2023, and entitled “Cosmetic Finish for Aluminum Alloys,” the entire disclosure of which is hereby incorporated by reference in its entirety.

### FIELD

The described embodiments relate generally to surface finish and materials of electronic devices. More particularly, the present embodiments relate to systems and methods for applying coatings that improve the cosmetics and enhance physical characteristics of aluminum substrates.

### BACKGROUND

Physical vapor deposition (PVD) is a method of providing a coating on a metal substrate, often used in industry to provide a protective and sometimes cosmetically appealing coating to metal parts. Generally during PVD, a solid material is vaporized in a vacuum and deposited onto the surface of a part. The nature of the PVD coating can depend on a number of factors, including the metal substrates and the process parameters used in the PVD processes. In some applications, a PVD coating is also colored, giving the metal part an attractive colored finish.

Unfortunately, when certain metal alloy substrates are used, the PVD coating can peel, chip or otherwise delaminate from their metal substrates when exposed to scratching or scraping forces during normal use of the part, or even during certain manufacturing operations such as drilling or machining which might be performed after applying a PVD coating. This delamination can cause the underlying metal substrate to be exposed at chipped or peeled regions of the anodic oxide coating, leaving visible chip marks and rendering the metal substrate more susceptible to corrosion. This delamination can be at least partially attributed to poor adhesion of the PVD coating to the metal substrate.

In addition to making the anodic oxide coating more susceptible to delamination, the PVD process itself requires conditions that can cause less durable aluminum alloys to crack, which can further result in corrosion or detract from the aesthetic appeal of the part.

### SUMMARY

An enclosure for an electronic device can include an aluminum substrate including a 6000 series aluminum or 7000 series aluminum, a PVD coating disposed on the substrate, and a protective underlayer disposed between the aluminum substrate and the PVD coating. In some examples, the protective underlayer prevents crazing of the aluminum substrate during application of the PVD coating. The protective underlayer can include an unsealed anodic oxide layer in some examples. In other examples, the protective underlayer can include a CrSn plating. The protective underlayer can include a thickness between about 9 μm and about 22 μm. In some examples, the aluminum substrate includes a 6013 series aluminum or a 7075 series aluminum. The aluminum substrate can include a die-cast aluminum.

A coating on a part that includes an aluminum substrate can include a barrier layer disposed on the aluminum substrate, a physical vapor disposition layer disposed on the barrier layer, and a color layer disposed on the physical vapor disposition layer. In some examples, the barrier layer can include an anodic oxide film. The anodic oxide film can be unsealed. In some examples, the barrier layer can include a chromium or titanium alloy. In some examples, the physical vapor disposition layer can include a seed layer disposed on the barrier layer, and a transition layer disposed between the seed layer and the color layer. The physical vapor disposition layer can include a thickness between about 2 μm and about 3.5 μm.

A method of applying a cosmetic finish to a part that includes a series 6000 or 7000 aluminum substrate can include forming an underlayer on the aluminum substrate and applying a PVD coating to the underlayer for at least 6 hours and at least 120° C. In some examples, forming the underlayer can include forming an unsealed anodized layer by anodizing the aluminum substrate with an electrolyte and applying a voltage between about 20 and 50 volts and a current density of about 10 to about 15 amperes per square foot. In some examples, forming the underlayer can include forming a plating stack that includes at least one of copper, chromium, zirconium, or titanium. In some examples, the method can further include chemically pre-treating the aluminum substrate prior to forming the underlayer on the aluminum substrate. In some examples, the PVD coating can be applied with about a 50% bias. In some examples, the method can further include applying a fluropolymer coating to the PVD coating. In some examples, forming the underlayer can increase an adhesion strength of the PVD coating and can prevent the galvanic corrosion of the metal alloy substrate.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows perspective views of devices having metallic surfaces that can be protected using PVD coatings, in accordance with some embodiments.

FIG. 2 shows a section view of a surface portion of an enclosure that includes an interface between a PVD coating and an aluminum substrate.

FIG. 3A shows a section view of a surface portion of an enclosure that includes an interface between a PVD coating and an unsealed anodized aluminum substrate.

FIG. 3B shows a section view of a surface portion of an enclosure that includes an interface between a PVD coating and a protective underlayer that includes a CrSn plating, in accordance with some embodiments.

FIG. 4A shows a section view of a plating stack, in accordance with some embodiments.

FIG. 4B shows a section view of a PVD stack, in accordance with some embodiments.

FIG. 4C shows a section view of a plating stack, in accordance with some embodiments.

FIG. 5 shows a flowchart indicating manufacturing processes that include a PVD coating applied to an aluminum substrate, in accordance with some embodiments.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates to processes for providing cosmetically appealing and durable physical vapor deposition (“PVD”) coatings on aluminum alloy substrates. Conventional PVD methods when applied to some aluminum alloys can result in corrosion of the substrate and a coating that has cosmetic defects or that is predisposed to delamination. Methods described herein involve application treatments that can be used to eliminate or reduce these cosmetic defects and to provide a well-adhered PVD coating.

In a particular embodiment, the methods and processes include forming or applying a barrier layer or an underlayer on the substrate. The barrier layer protects the substrate from the conditions of the PVD process to prevent and/or minimize corrosions. Additionally, the underlayer can improve the adhesion of the PVD coating to the substrate. Further, the processes and methods described herein can be used to create a cosmetically attractive surface on less refined and/or less cosmetic substrates. Consequently, a much wider possibility of aluminum alloy substrates for external enclosures and small parts of electronic devices can be utilized upon application of the processes disclosed herein. For example, substrates that can incorporate the present systems and methods can include die-cast alloys, very high strength alloys with significant second phase particles, welded enclosure structures, highly recycled alloys with more impurity content, and other alloys manufactured in different methods beyond extrusion and/or computer numerical control (CNC) machining.

The present disclosure is provided with specific reference to certain aluminum alloy substrates, such a 6000 series aluminum or 7000 series aluminum alloy substrates. It should be understood, however, that the methods described herein can be applicable to the treatment of any of a number of other suitable metal alloys, including aluminum alloy substrates that contain various alloying elements. In addition, aluminum alloy substrates where the metal matrix is formed of recycled metals or manufacturing processes that form alloys, such as die-casting aluminum, can also be used. In some examples, the metal matrix includes more than one type of alloy material. As used herein, the terms PVD film, PVD layer, and PVD coating can be used interchangeably and can refer to any suitable PVD process used in the manufacturing of the part or enclosure, unless otherwise specified. Further, as used herein, the terms barrier layer, underlayer, and protective underlayer can also be used interchangeably and can refer to a portion of the material cross section disposed between the aluminum substrate and the PVD coating.

Methods described herein are well suited for providing cosmetically appealing surface finishes to consumer products. For example, the methods described herein can be used to form durable and cosmetically appealing finishes for housing or enclosures for computers, portable electronic devices, and electronic device accessories.

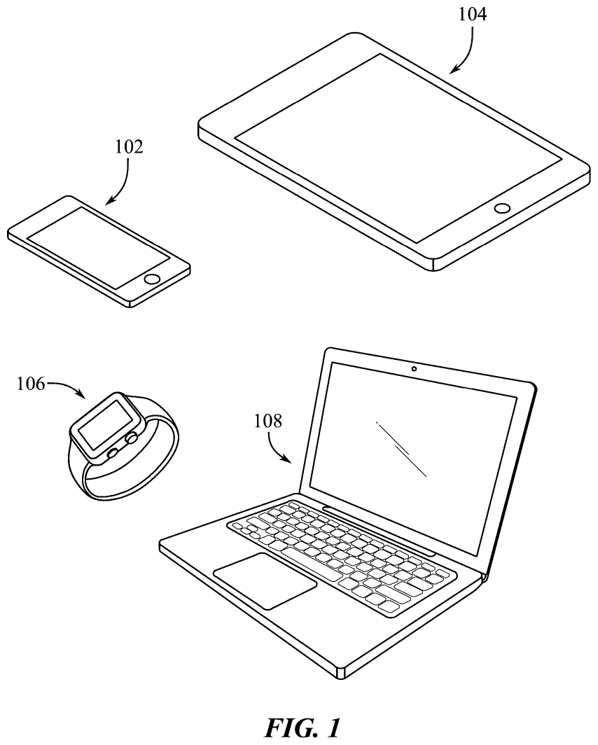

These and other embodiments are discussed below with reference to FIGS. 1-4. However, those skilled in the art will readily appreciate that the detailed description given herein with respect to these Figures is for explanatory purposes only and should not be construed as limiting. Furthermore, as used herein, a system, a method, an article, a component, a feature, or a sub-feature comprising at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

The methods and processes described herein can be used to form durable and cosmetically appealing coatings for metallic surfaces of consumer devices. FIG. 1 shows a number of example consumer products than can be manufactured using the methods and configurations described herein. FIG. 1 illustrates an example portable phone 102, tablet computer 104, a smart watch 106, and portable computer 108, which can each include metallic components and/or enclosures. The portable phone 102, tablet computer 104, smart watch 106, and portable computer 108 will be collectively described below as devices 102, 104, 106, and 108. During typical use, devices 102, 104, 106, and 108 can be subject to impact forces such as scratching, dropping, abrading, chipping, and gouging.

Typically, metal substrates are treated or clad in order to add a protective layer to these metal surfaces. The mechanical characteristics of aluminum offer multiple benefits for use in electronics and devices, especially where lightweight constructions are desired. However, it has been found that the adhesion strength of the coatings can depend, at least in part, on the type of metal used for the substrates. For example, some stronger aluminum alloys, although they can provide good structural integrity to devices 102, 104, 106, and 108, can also have surfaces that form coatings that are more prone to chipping, scratching and otherwise marring caused by impact forces. PVD processes represent an improved alternative to a number of conventional coating processes to deposit wear-resistant films on aluminum surfaces. In particular, conventional coating processes, such as claddings, can have a tendency to chip, spall, blister, or delaminate under surface impact, revealing the bare substrate alloy that can detract from the cosmetic appearance of devices 102, 104, 106, and 108. Metal surfaces at edges and corners of devices 102, 104, 106, and 108 can be especially vulnerable to this chipping and delamination. In addition, clad metals can be subjected to galvanic corrosion, which can result in failure of the device after ordinary use.

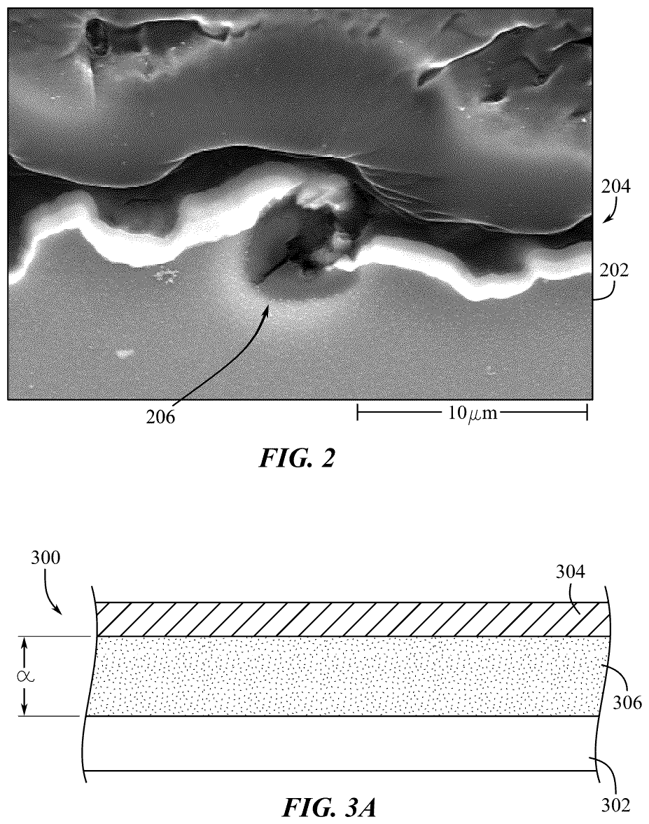

During the application of PVD to the aluminum alloy substrates, such as those forming metal surface of devices 102, 104, 106, and 108, any of a number of alloying elements can have a tendency to crack or craze due to the conditions the underlying substrate are subjected to during the PVD process. To illustrate, FIG. 2 shows an example PVD process applied directly to an aluminum substrate 202.

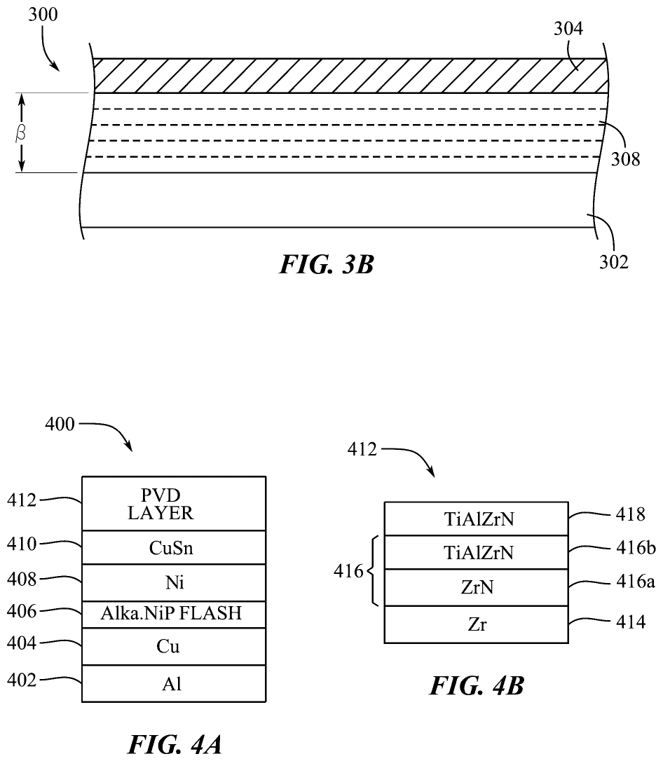

FIG. 2 illustrates a cross section of a PVD coating 204 applied directly to the aluminum alloy substrate 202. PVD coatings applied directly to the aluminum alloy substrate do not typically provide a sufficient corrosion barrier to prevent corrosion during normal use. A PVD coating 204, also known as thin-film coating, is a process in which a solid material is vaporized in a vacuum and deposited onto the surface of the substrate 202. The PVD coating 204 is not just a metal layer. Instead, compound materials can be deposited atom by atom, forming a thin, bonded, metal or metal-ceramic surface layer that can improve the appearance, durability, and/or function. In some examples, the PVD coating 204 can include a thickness between about 2 μm and about 3.5 μm. In some examples the PVD process occurs at about 140° C. As shown in FIG. 2, corrosion 206 can occur on the surface of the aluminum alloy substrate 202 through the PVD coating. Additionally, the PVD application process conditions can stress and corrode the substrate 202. Consequently, a barrier layer or an underlayer can be included on the surface of the substrate prior to the formation of the PVD coating to provide an acceptable corrosion barrier. FIG. 3A illustrates an example configuration.

FIG. 3A shows a section view of a surface portion of an enclosure 300 that includes an interface between a PVD coating 304 and an unsealed anodized aluminum substrate 302. In some examples, the aluminum substrate 302 can include a 6000 or 7000 series aluminum. The 6000 series aluminum is an aluminum alloy family that contains magnesium and silicon as predominate alloying components. Some beneficial properties of 6000 alloys include their extrudability, excellent strength, and high corrosion resistance. The 7000 series aluminum alloys contain zinc, and can also include copper, have relatively high strength values. In contrast, 6000 series aluminum has a higher elongation at break; in other words, the 6000 series aluminum can experience a greater deformation before it breaks, while 7000 series aluminum has a much higher tensile strength. Consequently, 6000 series aluminum or 7000 series aluminum can be desired for a variety of beneficial properties. According to one exemplary embodiment, the aluminum substrate 302 can include a 6013 aluminum alloy. The 6013 aluminum alloy can include magnesium, silicon, copper, manganese, iron, zinc, chromium, and titanium as minor alloying elements. In other examples, the aluminum substrate 302 can include a 7075 aluminum alloy. The 7075 aluminum alloy can include zinc as the primary alloying element. The 7075 aluminum alloy has excellent mechanical properties and exhibits good ductility, high strength, toughness, and good resistance to fatigue. The 7075 aluminum alloy can include about 5.6-6.1% zinc, 2.1-2.5% magnesium, 1.2-1.6% copper, and less than a half percent of silicon, iron, manganese, titanium, chromium, and other metals.

In some examples, the aluminum substrate 302 can include a die-cast aluminum. Aluminum die casting is a manufacturing process that can produce geometrically complex metal parts using reusable die casting molds, called dies. Cast aluminum is affordable and long-lasting. Additionally, aluminum die casting can be used to create very lightweight parts without sacrificing strength.

As shown in FIG. 3A, the PVD coating 304 is disposed on the aluminum substrate 302 with a protective underlayer 306 disposed between the aluminum substrate 302 and the PVD coating 304. As discussed briefly above, the protective underlayer 306 prevents crazing and corrosion of the aluminum substrate 302 during and/or after application of the PVD coating by providing a barrier between the substrate and PVD layer during application and also providing additional protection to the aluminum substrate 302 from corrosive elements at the surface (e.g., sweat, impacts, oils). Crazing is the propagation of visually perceptible cracks in a substrate when exposed to temperatures of about 80° C. or higher. Note that the PVD process can include operations at temperatures exceeding 80° C. After an exposure to high temperatures, the aluminum substrate 302 can be crazed and a high density of cracks can result in poor corrosion protection for the underlying substrate, particularly when exposed to corrosive environments.

The protective underlayer 306 can include an unsealed anodic oxide layer. In some examples, the anodic oxide underlayer 306 can be formed on the substrate 302 by anodizing the substrate 302 in an electrolyte. The anodic oxide underlayer 306 defines a coating over the substrate 302 to provide corrosion protection. In some examples, the anodic oxide protective underlayer 306 can include a thickness a between about 9 μm and about 22 μm. Anodization can have a duration in a range from about 30 minutes to about 60 minutes, or from about 35 to about 55 minutes, or from about 40 to about 50 minutes, or can be about 45 minutes. The thickness of the oxide underlayer 306 can be controlled in part by the duration of the anodization process. Anodic oxides can have a brittle characteristic, and can have a propensity to crack when they reach a certain level of tensile strain. The tensile limit and the corresponding tolerance to elevated temperature depends linearly on the thickness a of the anodic oxide underlayer 306.

As noted above, the anodic oxide underlayer 306 can be unsealed. Sealing the surface can include sealing the pores of the oxide underlayer 306. As temperature rises, the substrate metal, such as the aluminum substrate 302, expands more than the anodic oxide coating. The expansion places the anodic oxide underlayer 306 under a tensile strain, which is proportionate to temperature. A sealed anodic oxide is brittle and cracks when it reaches a level of tensile strain. As such, the anodic oxide underlayer 306 can remain unsealed to prevent crazing or corrosion. While the anodic oxide underlayer 306 can provide sufficient corrosion protection for the application of the PVD coating 304, other coatings can be applied to the aluminum substrate 302.

FIG. 3B shows a section view of a surface portion of an enclosure that includes an interface between a PVD layer and a protective underlayer that includes a barrier layer 308 having a plating stack, in accordance with some embodiments. In some examples, a coating 300 can include a barrier layer 308 disposed on the aluminum substrate 302. The coating 300 can further include a PVD coating or PVD layer 304 disposed on the barrier layer 308. In some examples, a color layer 310 can be disposed on the PVD layer 304.

The plating process, such as that used to form the barrier layer 308, is a manufacturing process in which a thin layer of metal is applied to coat a substrate. Metal plating provides benefits to the aluminum substrate 302, such as corrosion resistance and improved adhesion of the PVD layer 304. Plating can be applied through electroplating, which includes an electric current, or through electroless plating, which is in autocatalytic chemical process. In some examples, the barrier layer 308 can include a chromium or titanium alloy. In other examples, the barrier layer 308 can include a NiW-based plating. In yet other examples, the barrier layer 308 can include a SnCu-based plating. In some examples, the plating barrier layer 308 can include a thickness R between about 9 μm and about 22 μm.

Any of the features, components, and/or parts, including the arrangements and configurations thereof shown in FIGS. 3A-3B can be included, either alone or in any combination, in any of the other examples of devices, features, enclosures, coatings, and parts shown in the other figures described herein. Likewise, any of the features, enclosures, coatings, and/or parts, including the arrangements and configurations thereof shown and described with reference to the other figures can be included, either alone or in any combination, in the example of the devices, features, components, and parts shown in FIGS. 3A-3B.

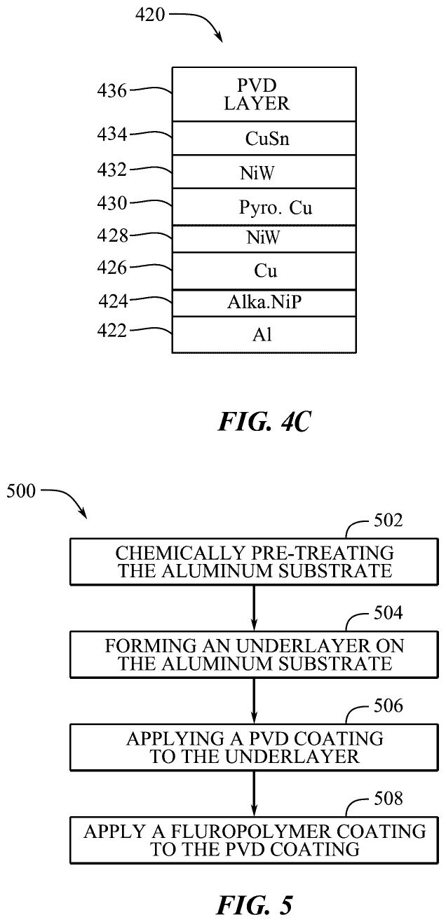

FIG. 4A shows a section view of an example plating stack 400, in accordance with some embodiments. The plating stack can be the same as the barrier layer 308 of FIG. 3B. In some examples, the plating stack 400 can include at least one plating layer applied to the aluminum substrate 402. The method of forming a plating stack such as plating stack 400 can include several steps that includes pretreatment, treatment, and post-treatment. In some examples, the aluminum substrate 402 is pretreated in preparation of the plating process. Pretreatment can include removing harmful contaminants, oils, and greases that may hinder the plating process from delivering uniform and satisfactory deposition rates. Pretreatment can include several steps of cleaning, rinsing, and other mechanical pretreatment processes, such as sanding, blasting, and/or finishing the aluminum substrate 402.

After pretreatment, the part and/or enclosure can be plated. The plating can include electroplating or electroless plating. Electroplating is the process of using electrodeposition to coat an object in a layer of metal(s). As shown in FIG. 4A, the aluminum substrate 402 is plated in copper layer 404. In some examples, a controlled electrolysis can be used to transfer the coating from an anode to the cathodic aluminum substrate 402. The anode and cathode are placed in an electrolyte chemical bath and exposed to a continuous electrical charge. The electricity causes negatively charged ions (anions) to move to the anode and positively charged ions (cations) to transfer to the cathode, covering or plating the aluminum substrate 402 in the plating material (e.g., copper layer 404). In some examples, the copper layer 404 can include a thickness greater than 2 μm. The thickness can be greater than 4 μm, greater than 6 μm, or greater than 8 μm, in some examples. The thickness of the copper layer 404 can be between about 2 μm and about 8 μm. In some examples, the specific thickness of the copper layer 404 can include a range between about 2 μm and about 4 μm, between about 4 μm and about 6 μm, between about 6 μm and about 8 μm, or more generally between about 3 μm and about 7 μm, in some examples. Electroplating takes the aluminum substrate 402 and encapsulates the substrate in the plating metal, such as copper. The electroplating can then be repeated in some examples. As shown in FIG. 4A, the copper plated aluminum substrate 402 can be further plated with a nickel platinum layer 406 and again plated with an electroless nickel plating layer 408.

In some examples, the nickel plating layer 408 can include a thickness greater than 2 μm. The thickness can be greater than 4 μm, greater than 6 μm, or greater than 8 μm, in some examples. The thickness of the nickel plating layer 408 can be between about 2 μm and about 8 μm. In some examples, the specific thickness of the nickel plating layer 408 can include a range between about 2 μm and about 4 μm, between about 4 μm and about 6 μm, between about 6 μm and about 8 μm, or more generally between about 3 μm and about 6 μm, in some examples.

In some examples, with the process of electroless nickel plating, a uniform thickness with high harness can be achieved. Electroless nickel plating can include the deposition of a nickel alloy onto the surface of the substrate by a chemical bath, not including electrodes or external electrical charges. Electroless nickel plating proves the plating of hard-to-reach surfaces, such as small bores and intricate shapes. Because of high corrosion resistance, nickel plating can be used without further hardening. Further, uniform thickness can be obtained on most surfaces. The deposition is controlled by the surface charge of the part to be plated. The adhesion strength of the electroless nickel plating depends on the ability of the metal to react with the plating solution. Adhesion further depends on the cleanliness of the surface prior to electroless nickel plating.

After the application of the electroless nickel plating layer 408, the plated aluminum substrate 402 can be further plated in a CuSn plating layer 410. The CuSn plating provides excellent adhesion for the PVD layer or stack 412, applied onto the CuSn plating layer 410. CuSn alloys, such as bronze, provides good resistance to element exposure (such as salt and sweat), are hard and polishable, and provide good wear resistance. In some examples, the CuSn plating layer 410 can include a thickness greater than 2 μm. The thickness can be greater than 4 μm, greater than 6 μm, or greater than 8 μm, in some examples. The thickness of the CuSn plating layer 410 can be between about 2 μm and about 8 μm. In some examples, the specific thickness of the CuSn plating layer 410 can include a range between about 2 μm and about 4 μm, between about 4 μm and about 6 μm, between about 6 μm and about 8 μm, or more generally between about 3 μm and about 5 μm, in some examples.

Finally, the PVD deposition layer can be applied to the CuSn plating layer 410. In some examples, the PVD deposition layer 412 can include a thickness greater than 1.5 μm. The thickness can be greater than 2 μm, greater than 3 μm, or greater than 4 μm, in some examples. The thickness of the PVD deposition layer 412 can be between about 1 μm and about 4 μm. In some examples, the specific thickness of the PVD deposition layer 412 can include a range between about 2 μm and about 3 μm, between about 3 μm and about 4 μm, between about 1.5 μm and about 3.5 μm, or more generally between about 1 μm and about 5 μm, in some examples.

FIG. 4B shows a section view of a PVD stack or PVD layer 412 as shown in FIG. 4A, in accordance with some embodiments. In some examples, the PVD stack 412 can include a seed layer 414 disposed on the barrier layer (e.g., protective underlayer 306) and a transition layer 416 including layers 416a and 416b. A color layer 418 can be disposed on the PVD layer 412. The transition layer 416 can be disposed between the seed layer 141 and the color layer 418. In some examples, the seed layer can include zirconium. Zirconium is a silver-gray transition metal that is malleable and ductile and easily forms stable compounds. Zirconium is also highly resistant to corrosion. In some examples, the seed layer 414 can include a thickness greater than 0.1 μm. The thickness can be greater than 0.2 μm, greater than 0.3 μm, or greater than 0.4 μm, in some examples. The thickness of the seed layer 414 can be between about 0.1 μm and about 0.5 μm. In some examples, the specific thickness of the seed layer 414 can include a range between about 0.1 μm and about 0.2 μm, between about 0.2 μm and about 0.3 μm, between about 0.3 μm and about 0.4 μm, or more generally between about 0.2 μm and about 0.4 μm, in some examples.

The PVD stack 412 can also include a zirconium nitride (ZrN) layer 416a. The ZrN grown by PVD can exhibit a light gold color similar to elemental gold. This layer 416a forms a thin, but very hard layer of ceramic substance on the surfaces. The ZrN layer 416a exhibits excellent corrosion and wear resistance. ZrN is bio-compatible, extremely tough and highly resistant against abrasive wear. In some examples, the zirconium nitride (ZrN) layer 416a can include a thickness greater than 0.4 μm. The thickness can be greater than 0.5 μm, greater than 0.7 μm, or greater than 0.8 μm, in some examples. The thickness of the zirconium nitride (ZrN) layer 416a can be between about 0.4 μm and about 0.8 μm. In some examples, the specific thickness of the zirconium nitride (ZrN) layer 416a can include a range between about 0.4 μm and about 0.6 μm, between about 0.6 μm and about 0.7 μm, between about 0.7 μm and about 0.8 μm, or more generally between about 0.4 μm and about 1 μm, in some examples.

In some examples, the PVD stack 412 can also include a titanium aluminum zirconium nitride (TiAlZrN) layer 416b as part of the transition layer 416. In some examples, TiAlZrN is known to have very high hardness, in excess of 40 GPa. In some examples, the zirconium nitride (TiAlZrN) layer 416b can include a thickness greater than 0.4 μm. The thickness can be greater than 0.5 μm, greater than 0.7 μm, greater than 0.8 μm, or greater than 1 μm, in some examples. The thickness of the zirconium nitride (TiAlZrN) layer 416b can be between about 0.4 μm and about 1 μm. In some examples, the specific thickness of the zirconium nitride (TiAlZrN) layer 416b can include a range between about 0.4 μm and about 0.6 μm, between about 0.6 μm and about 0.8 μm, between about 0.8 μm and about 1 μm, or more generally between about 0.4 μm and about 1.2 μm, in some examples.

As such, the PVD stack 412 also includes the color layer 418 of TiAlZrN. The multi-layer structure of the PVD stack 412 provides high levels of hardness and toughness. The zirconium-based top layer minimizes the chemical reaction between the coating and the environment. In some examples, the color layer 418 of TiAlZrN can include a thickness greater than 0.7 μm. The thickness can be greater than 1 μm, greater than 1 μm, greater than 1.2 μm, or greater than 1.3 μm, in some examples. The thickness of the color layer 418 of TiAlZrN can be between about 0.7 μm and about 1.3 μm. In some examples, the specific thickness of color layer 418 of TiAlZrN can include a range between about 0.7 μm and about 0.9 μm, between about 0.9 μm and about 1.1 μm, between about 1.1 μm and about 1.3 μm, or more generally between about 0.7 μm and about 1.5 μm, in some examples. In some examples, the PVD layer 412 can include a total thickness between about 2 μm and about 3.5 μm.

FIG. 4C shows a section view of an example plating stack 420, in accordance with some exemplary embodiments. The plating stack can be the same as, or similar to, the barrier layer 308 of FIG. 3B. In some examples, the plating stack 420 can include at least one plating layer applied to the aluminum substrate 422. The method of forming a plating stack such as plating stack 420 can include several steps that include pretreatment, treatment, and post-treatment. In some examples, the aluminum substrate 422 is pretreated in preparation of the plating process.

After pretreatment, the part and/or enclosure can be plated. The plating can include electroplating or electroless plating. Electroplating can include using electrodeposition to coat an object in a layer of metal(s). As shown in FIG. 4C, an electroless nickel plating layer or layer 424 of alkaline nickel phosphate can be applied to the aluminum substrate 422.

Electroless nickel plating can include the deposition of a nickel alloy onto the surface of the substrate by a chemical bath, not including electrodes or external electrical charges. Because of high corrosion resistance, nickel plating can be used without further hardening. In some examples, the final part and/or enclosure can exhibit a layer of the alkaline nickel phosphate can include a thickness between about 0.5 and about 4 microns, or between about 1 and about 2 microns. In some examples, the alkaline nickel phosphate layer 424 can include a thickness greater than 1 μm. The thickness can be greater than 1.5 μm, or greater than 2 μm, in some examples. The thickness of the alkaline nickel phosphate layer 424 can be between about 0.5 μm and about 2.5 μm. In some examples, the specific thickness of the alkaline nickel phosphate layer 424 can include a range between about 0.5 μm and about 1 μm, between about 1 μm and about 1.5 μm, between about 1.5 μm and about 2.5 μm, or more generally between about 0.5 μm and about 3 μm, in some examples.

Then the substrate 422 can then be plated in copper layer 426. In some examples, a controlled electrolysis can be used to transfer the coating from an anode to the cathodic aluminum substrate 422. The anode and cathode can be placed in an electrolyte chemical bath and exposed to a continuous electrical charge. The electricity causes negatively charged ions (anions) to move to the anode and positively charged ions (cations) to transfer to the cathode, covering or plating the aluminum substrate 422 in the plating material (e.g., copper layer 426). In some examples, the final part and/or enclosure can exhibit a layer of copper that can include a thickness between about 2 and about 9 microns, or between about 3 and about 7 microns. In some examples, the copper layer 426 can include a thickness greater than 2 μm. The thickness can be greater than 4 μm, greater than 6 μm, or greater than 8 μm, in some examples. The thickness of the copper layer 426 can be between about 2 μm and about 8 μm. In some examples, the specific thickness of the copper layer 426 can include a range between about 2 μm and about 4 μm, between about 4 μm and about 6 μm, between about 6 μm and about 8 μm, or more generally between about 3 μm and about 7 μm, in some examples. The electroplating can then be repeated.

As shown in FIG. 4C, the copper plated aluminum substrate 422 can be further plated with a nickel tungsten layer 428. The NiW-based layer can provide a hard layer in the plating to maximize performance in durability and impact resistance, maintaining delamination performance. In some examples, the final part and/or enclosure can exhibit a layer of nickel tungsten that can include a thickness between about 1 and about 6 microns, or between about 3 and about 5 microns. In some examples, the nickel tungsten layer 428 can include a thickness greater than 2 μm. The thickness can be greater than 4 μm, greater than 6 μm, or greater than 8 μm, in some examples. The thickness of the nickel tungsten layer 428 can be between about 2 μm and about 8 μm. In some examples, the specific thickness of the nickel tungsten layer 428 can include a range between about 2 μm and about 4 μm, between about 4 μm and about 6 μm, between about 6 μm and about 8 μm, or more generally between about 3 μm and about 5 μm, in some examples.

Incorporating the harder NiW plating layers can also provide a better transition to the hard PVD layer at an exterior of the part and/or enclosure. A pyrophosphate copper layer 430 can then be added. The pyrophosphate copper layer 430 can maintain a matte appearance at an outer surface of the part and/or enclosure. In some examples, the final part and/or enclosure can exhibit a layer of pyrophosphate copper that can include a thickness between about 3 and about 5 microns. In some examples, the pyrophosphate copper layer 430 can include a thickness greater than 2 μm. The thickness can be greater than 4 μm, greater than 6 μm, or greater than 8 μm, in some examples. The thickness of the pyrophosphate copper layer 430 can be between about 2 μm and about 8 μm. In some examples, the specific thickness of the pyrophosphate copper layer 430 can include a range between about 2 μm and about 4 μm, between about 4 μm and about 6 μm, between about 6 μm and about 8 μm, or more generally between about 3 μm and about 5 μm, in some examples.

The electroplating can then be repeated. The part and/or enclosure can again be plated with an electroless nickel tungsten plating layer 432. In some examples, the final part and/or enclosure can exhibit a second layer of nickel tungsten that can include a thickness between about 2 and about 10 microns, or between about 4 and about 7 microns. In some examples, the nickel tungsten layer 432 can include a thickness greater than 2 μm. The thickness can be greater than 4 μm, greater than 6 μm, or greater than 8 μm, in some examples. The thickness of the nickel tungsten layer 432 can be between about 2 μm and about 8 μm. In some examples, the specific thickness of the nickel tungsten layer 432 can include a range between about 3 μm and about 5 μm, between about 4 μm and about 6 μm, between about 5 μm and about 7 μm, or more generally between about 3 μm and about 8 μm, in some examples.

In some examples, with the process of electroless nickel plating with nickel tungsten, a uniform thickness with high harness can be achieved. Further, uniform thickness can be obtained on most surfaces. The deposition can be controlled by the surface charge of the part to be plated. The adhesion strength of the electroless nickel tungsten plating can depend at least in part on the ability of the metal to react with the plating solution. Adhesion can further depend on the cleanliness of the surface prior to electroless nickel plating.

After the application of the second electroless nickel tungsten plating layer 432, the plated aluminum substrate 422 can be further plated in a CuSn plating layer 434. The CuSn plating can provide excellent adhesion for the PVD layer or stack 436, applied onto the CuSn plating layer 434. In some examples, the final part and/or enclosure can exhibit a layer of copper tin that can include a thickness between about 1 and about 7 microns, or between about 3 and about 5 microns. In some examples, the CuSn plating layer 434 can include a thickness greater than 2 μm. The thickness can be greater than 4 μm, greater than 6 μm, or greater than 8 μm, in some examples. The thickness of the CuSn plating layer 434 can be between about 2 μm and about 8 μm. In some examples, the specific thickness of the CuSn plating layer 434 can include a range between about 2 μm and about 4 μm, between about 4 μm and about 6 μm, between about 6 μm and about 8 μm, or more generally between about 3 μm and about 5 μm, in some examples.

Finally, the PVD deposition layer 436 can be applied to the CuSn plating layer 434. In some examples, the final part and/or enclosure can exhibit a layer of PVD that can include a thickness between about 1 and about 5 microns, or between about 2 and about 3.5 microns. In some examples, the PVD deposition layer 436 can include a thickness greater than 1 μm. The thickness can be greater than 3 μm, greater than 5 μm, or greater than 6 μm, in some examples. The thickness of the PVD deposition layer 436 can be between about 1 μm and about 4 μm. In some examples, the specific thickness of the PVD deposition layer 436 can include a range between about 1 μm and about 2 μm, between about 2 μm and about 3 μm, between about 3 μm and about 4 μm, or more generally between about 1 μm and about 5 μm, in some examples.

Any of the features, components, and/or parts, including the arrangements and configurations thereof shown in FIGS. 4A-4C can be included, either alone or in any combination, in any of the other examples of devices, features, enclosures, coatings, and parts shown in the other figures described herein. Likewise, any of the features, enclosures, coatings, and/or parts, including the arrangements and configurations thereof shown and described with reference to the other figures can be included, either alone or in any combination, in the example of the devices, features, coatings, and parts shown in FIGS. 4A-4C.

FIG. 5 shows a flowchart indicating manufacturing processes that include a PVD coating applied to an aluminum substrate, in accordance with some embodiments. In some examples, a method 500 of applying a cosmetic finish to a part that includes a series 6000 or 7000 aluminum substrate. In some examples, the method 500 can include act 502 of chemically pretreating the aluminum substrate prior to forming the underlayer on the aluminum substrate. In some examples, Chemical treatment of the part significantly affects its brightness (specularity). Chemical treatment can be performed prior to anodizing and can be an important factor in the final appearance of the anodized part. The pre-anodization chemical treatment of aluminum is often cleaning, clean-up or pretreatment phase of the process. In some examples, a typical chemical treatment process can include at least one of treatment in an inhibited acid or alkaline cleaner to remove dirt and oils, and/or deoxidize in strong acidic solution to remove natural oxides or heat-treat scale. Further, in some examples, chemical etching can be included. Etching removes a very thin surface layer of material and can remove the native oxide film so that the part can be anodized successfully.

Similarly, plating can include chemical pretreatment to remove greases, oils, imperfections and other contaminants. In general, the pretreatment process cleans the substrate with a series of base or acid chemicals. In between each chemical treatment, the substrate can be rinsed with water to sufficiently remove residual chemical adhesion. Degreasing can remove contaminant oils, and further acid cleaning can remove scaling. An alkaline zincate can be beneficial to remove contaminants from aluminum alloys.

The method 500 can include the act 504 of forming an underlayer on the aluminum substrate. In some examples, act 504 can include forming an unsealed anodized layer by anodizing the aluminum substrate with an electrolyte and applying a voltage between about 20 and 50 volts and a current density of about 10 to about 15 amperes per square foot. Act 504 can include other conditions for anodizing the aluminum substrate, such as applying a higher or lower voltage and/or current density.

In some examples, act 504 of forming an underlayer on the substrate can include forming a plating stack that includes at least one of copper, chromium, zirconium, or titanium. The plating stack can include electroplating or electroless plating and can be formed as described above. For example, a controlled electrolysis can be used to transfer the coating from an anode to the cathodic aluminum substrate. The anode and cathode are placed in an electrolyte chemical bath and exposed to a continuous electrical charge. The electricity causes negatively charged ions (anions) to move to the anode and positively charged ions (cations) to transfer to the cathode, covering or plating the aluminum substrate in the plating material (e.g., copper layer 404). Electroless nickel plating can include the deposition of a nickel alloy onto the surface of the substrate by a chemical bath, not including electrodes or external electrical charges.

The method 500 can further include the act 506 of applying a PVD coating to the underlayer. In some examples, the PVD coating can be applied by vaporizing a source material to a plasma of atoms or molecules and depositing them onto the underlayer. In some examples, the specific application process can be by sputtering or thermal evaporation. Sputtering is a thin film coating technique wherein the coating material is given an electrical charge causing it to be bombarded with ionized gas molecules in a vacuum environment, causing atoms of the PVD material to be “sputtered” off into the plasma. The vaporized atoms can then be deposited when they condense as a thin film on the underlayer. Thermal evaporation deposition can include heating a solid PVD material inside a high vacuum chamber to a temperature that produces a vapor pressure sufficient to raise a vapor cloud inside the chamber. The evaporated PVD material as a vapor stream traverses the chamber and contacts the underlayer, forming the coating or film. In some examples, the PVD coating can be applied to the underlayer for at least 6 hours and at least 120° C. In some examples, the PVD coating can be applied at about 140° C. for about 8 hours.

In some examples, the PVD coating is applied with a bias voltage. In some examples, the bias voltage can be between about 30% bias and about 70% bias, or more particularly about a 50% bias voltage. The bias voltage during a PVD process affects the coating properties and adhesion. The larger bias voltage, the higher the film strength and endurance are. However, the film adhesion can deteriorate by increasing the bias voltage. As such, the approximately 50% bias voltage provides a balance between the adhesion and the strength of the PVD coating.

In some examples, the method 500 can further include the act 508 of applying a fluoropolymer coating to the PVD coating. A fluoropolymer is a polymer that is based in fluorocarbon and has strong carbon-fluoride bonds. Fluoropolymers reduce friction and resist corrosion. Fluoropolymers withstand very high temperatures, and are insulators, meaning they do not conduct electricity. Similarly, fluoropolymers do not absorb water. In other words, the fluoropolymer coating protects the enclosure from wear and tear and extends the lifespan of the device.

In some examples, the method 500 can eliminate or reduce cosmetic defects when applied to enclosures of electronic devices and parts and also provide a well-adhered PVD coating. The devices and parts can incorporate a variety of aluminum alloy substrates for external enclosures and small parts of electronic devices. The aluminum alloy substrates can be of a non-cosmetic quality. In some examples, the coating enhances the physical characteristics of aluminum substrates and protects the substrate from corrosion.

To the extent applicable to the present technology, gathering and use of data available from various sources can be used to improve the delivery to users of invitational content or any other content that may be of interest to them. The present disclosure contemplates that in some instances, this gathered data may include personal information data that uniquely identifies or can be used to contact or locate a specific person. Such personal information data can include demographic data, location-based data, telephone numbers, email addresses, TWITTER® ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide mood-associated data for targeted content delivery services. In yet another example, users can select to limit the length of time mood-associated data is maintained or entirely prohibit the development of a baseline mood profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. An enclosure for a portable electronic device, the enclosure comprising:
an aluminum substrate comprising a 6000 series aluminum or a 7000 series aluminum;
a PVD coating disposed on the substrate; and
a protective underlayer disposed between the aluminum substrate and the PVD coating.

2. The enclosure of claim 1, wherein the protective underlayer prevents crazing of the aluminum substrate during application of the PVD coating.

3. The enclosure of claim 1, wherein the protective underlayer comprises an unsealed anodic oxide layer.

4. The enclosure of claim 1, wherein the protective underlayer comprises a CrSn plating.

5. The enclosure of claim 1, wherein the protective underlayer comprises a thickness between about 9 μm and about 22 μm.

6. The enclosure of claim 1, wherein the aluminum substrate comprises a 6013 series aluminum or a 7075 series aluminum.

7. The enclosure of claim 1, wherein the aluminum substrate comprises a die-cast aluminum.

8. A coating on an aluminum substrate, the coating comprising:
a barrier layer disposed on the aluminum substrate;
a physical vapor disposition layer disposed on the barrier layer; and
a color layer disposed on the physical vapor disposition layer.

9. The coating of claim 8, wherein the barrier layer comprises an anodic oxide film.

10. The coating of claim 9, wherein the anodic oxide film is unsealed.

11. The coating of claim 8, wherein the barrier layer comprises a chromium alloy or a titanium alloy.

12. The coating of claim 8, wherein the physical vapor disposition layer comprises:
a seed layer disposed on the barrier layer; and
a transition layer disposed between the seed layer and the color layer.

13. The coating of claim 8, wherein the physical vapor disposition layer comprises a thickness between about 2 μm and about 3.5 μm.

14. A method of applying a cosmetic finish to a part comprising a series 6000 or 7000 aluminum substrate, the method comprising:
forming an underlayer on the aluminum substrate; and
applying a PVD coating to the underlayer for at least 6 hours and at least 120° C.

15. The method of claim 14, wherein forming the underlayer comprises forming an unsealed anodized layer by anodizing the aluminum substrate with an electrolyte and applying a voltage between about 20 and 50 volts and a current density of about 10 to about 15 amperes per square foot.

16. The method of claim 14, wherein forming the underlayer comprises forming a plating stack comprising at least one of copper, chromium, zirconium, or titanium.

17. The method of claim 14, further comprising chemically pre-treating the aluminum substrate prior to forming the underlayer on the aluminum substrate.

18. The method of claim 14, wherein the PVD coating is applied with about a 50% bias.

19. The method of claim 14, further comprising applying a fluropolymer coating to the PVD coating.

20. The method of claim 14, wherein forming the underlayer increases an adhesion strength of the PVD coating and prevents the galvanic corrosion of the aluminum substrate.
